(19) United States
(12) Patent Application Publication
(10) Pub. No.: US 2018/0294350 A1
(43) Pub. Date: Oct. 11, 2018

(54) SILICON CARBIDE SEMICONDUCTOR DEVICE AND METHOD OF MANUFACTURING SILICON CARBIDE SEMICONDUCTOR DEVICE

(71) Applicant: Fuji Electric Co., Ltd., Kanagawa (JP)

(72) Inventors: Makoto UTSUMI, Nagano (JP); Akimasa KINOSHITA, Nagano (JP)

(73) Assignee: Fuji Electric Co., Ltd., Kanagawa (JP)

(21) Appl. No.: 15/911,740

(22) Filed: Mar. 5, 2018

(30) Foreign Application Priority Data
Apr. 11, 2017 (JP) 2017-078557

(51) Int. Cl. H01L 29/78; H01L 29/16; H01L 29/417; H01L 29/66; H01L 29/423; H01L 21/02; H01L 21/768; H01L 29/45

(52) U.S. Cl. CPC H01L 29/7813; H01L 29/1608; H01L 29/41741; H01L 29/66068; H01L 29/66734; H01L 29/0882; H01L 21/02129; H01L 21/76802; H01L 21/76828; H01L 21/76843; H01L 29/45; H01L 29/4236

(57) ABSTRACT

A trench gate structure vertical MOSFET includes a silicon carbide substrate of a first conductivity type, a first semiconductor layer of the first conductivity type, a second semiconductor layer of a second conductivity type, first semiconductor regions of the first conductivity type, a trench, a gate electrode, an interlayer insulating film, a barrier layer, a contact electrode, a first electrode, and a second electrode. The barrier layer includes a layer made of TiN, and the thickness of the TiN layer is 10 to 80 nm. The interlayer insulating film is a laminate film of non-doped silicate glass and borophosphosilicate glass.

### BACKGROUND OF THE INVENTION

### Technical Field

The present invention relates to a silicon carbide semiconductor device and a method of manufacturing a silicon carbide semiconductor device.

### Background Art

Silicon carbide (SiC) is expected to be the next generation of semiconductor material, replacing silicon (Si). A semiconductor element (hereinafter, silicon carbide semiconductor device) that uses silicon carbide as a semiconductor material has various advantages over a conventional semiconductor element using silicon as the semiconductor material, such as the ability to lower the resistance of the device during ON to several hundredths of that of the conventional device, and the ability to use the device in a higher temperature (200° C. or more) environment. This is because of the features of silicon carbide itself, which has a bandgap approximately three times greater than that of silicon and an insulation breakdown electric field strength that is almost an order of magnitude greater than silicon.

Currently, commercially available silicon carbide semiconductor devices include SBDs (Schottky barrier diodes), vertical MOSFETs (metal oxide semiconductor field effect transistors) of planar gate structure and trench gate structure.

The trench gate structure is a three-dimensional structure in which a MOS gate (an insulated gate made of metal-oxide film-semiconductor) is embedded inside a trench formed in a semiconductor substrate (hereinafter, silicon carbide substrate) made of silicon carbide, with the portion along the trench side walls being used as the channel (inversion layer). Thus, when comparing devices of the same resistance (Ron), the trench gate structure can have a predominantly smaller device area (chip area) than a planar gate structure in which the MOS gate is provided in a flat-plate shape on the silicon carbide substrate. This device structure shows a promising future.

The structure of a conventional silicon carbide semiconductor device will be described while using a trench gate structure vertical MOSFET as an example. FIG. 12 is a cross-sectional view showing the structure of a conventional silicon carbide semiconductor device. The conventional silicon carbide semiconductor device shown in FIG. 12 includes an ordinary trench gate structure MOS gate on the front surface (surface on the p-type base layer 6 side) side of a semiconductor substrate (hereinafter, silicon carbide substrate) 100 made of silicon carbide. The silicon carbide substrate (semiconductor chip) 100 is formed by epitaxially growing silicon carbide layers of an n drift layer 2, n-type current spreading region 5, and p-type base layer 6 in the stated order on an n⁺ support substrate (hereinafter, n⁺ silicon carbide substrate) 1 made of silicon carbide.

Second p⁺ regions 4 are selectively provided in the n-type current spreading region 5 so as to cover the entire bottom surfaces of trenches 18. The second p-type regions 4 are provided at a depth that does not reach the n⁻ drift region 2. First p⁺ regions 3 are also selectively provided in the n-type current spreading region 5 between adjacent trenches 18 (mesa parts). The first p⁺ type regions 3 contact the p-type base layer 6 and are provided at a depth that does not reach the n drift region 2. Reference characters 7, 8, 9, 10, 11, 12, 13, 14, and 15 are, respectively, an n⁺ source region, p⁺ contact region, gate insulating film, gate electrode, interlayer insulating film, barrier metal, contact electrode, source electrode, and drain electrode.

The interlayer insulating film 11 is provided to electrically insulate the source electrode 14 from the gate electrode 10. The interlayer insulating film 11 is made of BPSG (borophosphosilicate glass), for example. When made of BPSG, the top of the interlayer insulating film is rounded due to a thermal treatment, which improves coverage characteristics with the source electrode 14 that is made of an Al (aluminum)-Si (silicon) alloy.

The barrier metal 12 is provided to prevent the diffusion of metal atoms from the source electrode 14 toward the gate electrode 10 side. Using TiN as the barrier metal 12, for example, prevents the intrusion of Ni (nickel) into an n-type region such as the n⁺ source regions 7 when forming Ni silicide of the contact electrode 13. Furthermore, TiN prevents the high temperature or heat during forming of the Ni silicide or the plasma from etching the Ti film from affecting the gate insulating film 9. The source electrode 14 is made of an Al—Si alloy and Ti film. Ti is a metal that stores hydrogen (H); thus, Ti can prevent fluctuations in the threshold voltage Vth caused by adverse effects from external hydrogen ions.

There is a technique for using BPSG as the interlayer insulating film 11 and using TiN as the barrier metal (see Patent Document 1, for example). TiN prevents boron (B), phosphorous (P), sodium (Na), or the like in the BPSG from contaminating the source contact surface, and further prevents intrusion of Al—Si—Ti alloy components used in the contact electrode from intruding into the interlayer insulating film.

There is also a technique for forming an infrared ray absorption film made of TiN on an interlayer insulating film (see Patent Document 2, for example). The thickness of the infrared absorption film is set to 10 nm or more in order to absorb infrared rays and set to 300 nm or less to prevent cracking. There is also a technique for using, as the interlayer insulating film, a multilayer film made of NSG (non-doped silicate glass) and BPSG, and TiN for the barrier metal (see Patent Document 3, for example). The barrier metal film made of TiN is formed with a thickness of 100 nm, a first interlayer insulating film made of NSG is formed with a thickness of 200 nm, and a second interlayer insulating film made of BPSG with a phosphorous concentration of 2.7 wt % and boron concentration of 3.6 wt %, for example, is formed with a thickness of 700 nm on the first interlayer insulating film. In order to obtain a smooth reflow shape, there is a technique of using BPSG as the interlayer insulating film and setting the total content of boron oxide (B₂O₃) and phosphorous pentoxide (P₂O₅) in the BPSG to be within a range of 8 to 15 mol % (see Patent Document 4, for example).

### RELATED ART DOCUMENTS

### Patent Documents

Patent Document 1: Japanese Patent Application Laid-Open Publication No. 2016-86064

Patent Document 2: Japanese Patent No. 5885284

Patent Document 3: Japanese Patent Application Laid-Open Publication No. 2013-232560

Patent Document 4: Japanese Patent Application Laid-Open Publication No. 2002-76342

### SUMMARY OF THE INVENTION

In a trench gate structure vertical MOSFET, it is possible to narrow the cell pitch as described above. In such a case, in order to planarize the interlayer insulating film 11 and improve coverage characteristics, BPSG is used as the interlayer insulating film 11. However, if TiN is used in the barrier metal 12, the thermal expansion coefficients of BPSG and TiN will differ; therefore, when applying heat for silicidation of the contact electrode 13, the deformation of the BPSG will not follow the deformation of the TiN, thus causing cracks such as tears and cleavage or detachment in the BPSG. In Patent Documents 1 and 2 described above, there is no consideration given to the deformation of BPSG caused by heating of the contact electrode 13, and thus cracking or detachment of the BPSG may occur. If cracking or detachment occur, the insulation characteristics between the source electrode 14 and gate electrode 10 will suffer, causing fluctuations in the threshold voltage Vth and leading to deterioration of semiconductor device characteristics.

If the film thickness of TiN were made thin, there would be less deformation of TiN, and BPSG could follow the deformation of TiN and prevent cracking. Furthermore, cracking and detachment of the BPSG could also be prevented if TiN were not used in the barrier metal 12. However, in such a case, the TiN being thin or non-existent would cause the high temperature or heat during forming the Ni silicide or the plasma for etching the Ti film to affect the gate insulating film 9, thereby causing fluctuations in threshold voltage Vth and leading to deterioration of semiconductor device characteristics.

In order to eliminate the problems of the conventional technology described above, the present invention aims at providing a silicon carbide semiconductor device and method of manufacturing a silicon carbide semiconductor device that can prevent cracking or detachment and suppress fluctuations in threshold voltage Vth when using BPSG as an interlayer insulating film and TiN as a barrier metal.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a silicon carbide semiconductor device, including: a silicon carbide substrate of a first conductivity type; a first semiconductor layer of the first conductivity type, provided on or over a front surface of the silicon carbide substrate; a second semiconductor layer of a second conductivity type, provided on the first semiconductor layer on a side opposite to the silicon carbide substrate; first semiconductor regions of the first conductivity type, selectively provided in a top surface of the second semiconductor layer; a trench penetrating through the second semiconductor layer and the first semiconductor regions and reaching the first semiconductor layer; a gate electrode provided inside the trench with a gate insulating film interposed therebetween; an interlayer insulating film covering the gate electrode; a layer made of TiN covering the interlayer insulating film; a contact electrode contacting the second semiconductor layer; a first electrode over the layer made of TiN, electrically connecting to the contact electrode and the first semiconductor regions; and a second electrode provided on a rear surface of the silicon carbide substrate, wherein a film thickness of the layer made of TiN is 10 to 80 nm, and wherein the interlayer insulating film is a laminate film of a layer of non-doped silicate glass and a layer of borophosphosilicate glass.

In the aforementioned silicon carbide semiconductor device, the film thickness of the layer made of TiN may be 20 to 70 nm.

In the aforementioned silicon carbide semiconductor device, a concentration of boron in the borophosphosilicate glass may be 6 to 7.5 mol %, a concentration of phosphorous in the borophosphosilicate glass may be 1 to 3 mol %, a film thickness of the non-doped silicate glass may be 40 to 200 nm, and a film thickness of the borophosphosilicate glass may be 200 to 1,000 nm.

In the aforementioned silicon carbide semiconductor device, the layer made of TiN may be formed in substantially all regions that excludes a region where the contact electrode contacts the second semiconductor layer.

In the aforementioned silicon carbide semiconductor device, a concentration of boron in the borophosphosilicate glass may be 6 to 7.5 mol %, a concentration of phosphorous in the borophosphosilicate glass may be 1 to 3 mol %, a film thickness of the non-doped silicate glass may be 40 to 200 nm, and a film thickness of the borophosphosilicate glass may be 200 to 1,000 nm.

In the aforementioned silicon carbide semiconductor device, the layer made of TiN may be formed in substantially all regions that exclude a region where the contact electrode contacts the second semiconductor layer.

In the aforementioned silicon carbide semiconductor device, the contact electrode may contact the second semiconductor layer through a contact region of the second conductivity type selectively that is formed in the top surface of the second semiconductor layer, an impurity concentration of the contact region being higher than an impurity concentration of the second semiconductor layer.

In the aforementioned silicon carbide semiconductor device, in the interlayer insulating film the layer of non-doped silicate glass may be under the layer of borophosphosilicate glass.

In another aspect, the present disclosure provides a method of manufacturing a silicon carbide semiconductor device, the method including: a first step of forming a first semiconductor layer of a first conductivity type on or over a front surface of a silicon carbide substrate of the first conductivity type; a second step of forming a second semiconductor layer of a second conductivity type on the first semiconductor layer on a side opposite to the silicon carbide substrate; a third step of selectively forming first semiconductor regions of the first conductivity type in a top surface of the second semiconductor layer; a fourth step of forming a trench penetrating through the second semiconductor layer and the first semiconductor regions and reaching the first semiconductor layer; a fifth step of forming a gate electrode inside the trench with a gate insulating film interposed therebetween; a sixth step of forming an interlayer insulating film covering the gate electrode; a seventh step of forming a layer made of TiN covering the interlayer insulating film; an eighth step of forming a contact electrode contacting and the second semiconductor layer; a ninth step of forming a first electrode over the layer made of TiN, electrically connecting to the contact electrode and the first semiconductor regions; and a tenth step of forming a second electrode on a rear surface of the silicon carbide substrate, wherein in the seventh step, the layer made of TiN is formed to have a film thickness of 10 to 80 nm, and wherein in the sixth step, the interlayer insulating film is formed of a laminate film of a layer of non-doped silicate glass and a layer of borophosphosilicate glass.

In the aforementioned method of manufacturing the silicon carbide semiconductor device, after the seventh step is performed, the eighth step may be performed, and in the eighth step, a thermal treatment may be performed during forming of the contact electrode.

In the aforementioned method of manufacturing the silicon carbide semiconductor device, a temperature of the thermal treatment may be higher than a glass transition temperature of the borophosphosilicate glass.

In the aforementioned method of manufacturing the silicon carbide semiconductor device, the contact electrode may contact the second semiconductor layer through a contact region of the second conductivity type selectively that is formed in the top surface of the second semiconductor layer, an impurity concentration of the contact region being higher than an impurity concentration of the second semiconductor layer.

In the aforementioned method of manufacturing the silicon carbide semiconductor device, in the interlayer insulating film, the layer of non-doped silicate glass may be under the layer of borophosphosilicate glass.

The disclosure described above provides a TiN film with a thickness of 10 to 80 nm as the barrier metal. The thickness of the TiN film being 10 nm or more makes it possible to prevent high temperature, light irradiation, and plasma from affecting the gate insulating film, thus making it possible to prevent intrusion of Ni into n-type regions in the step of silicidation. The thickness of the TiN being 100 nm or less makes it possible to prevent the BPSG from cracking. Therefore, it is possible to prevent fluctuations in the threshold voltage Vth and a deterioration of semiconductor device characteristics. The interlayer insulating film is laminated in the order of PSG and BPSG. This improves coverage characteristics with a source electrode made of Al—Si.

The silicon carbide semiconductor device and method of manufacturing the silicon carbide semiconductor device of the present disclosure can prevent cracking or detachment and suppress fluctuations in threshold voltage Vth when using BPSG in an interlayer insulating film and TiN in a barrier metal.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view of a structure of a silicon carbide semiconductor device according to an embodiment.

FIG. 2 is a flowchart showing an overview of a part of the process for a method of manufacturing a silicon carbide semiconductor device of an embodiment.

FIG. 3 is a cross-sectional view of the silicon carbide semiconductor device of the embodiment during manufacturing (first part).

FIG. 4 is a cross-sectional view of the silicon carbide semiconductor device of the embodiment during manufacturing (second part).

FIG. 5 is a cross-sectional view of the silicon carbide semiconductor device of the embodiment during manufacturing (third part).

FIG. 6 is a cross-sectional view of the silicon carbide semiconductor device of the embodiment during manufacturing (fourth part).

FIG. 7 is a cross-sectional view of the silicon carbide semiconductor device of the embodiment during manufacturing (fifth part).

FIG. 8 is a cross-sectional view of the silicon carbide semiconductor device of the embodiment during manufacturing (sixth part).

FIG. 9 is a cross-sectional view of the silicon carbide semiconductor device of the embodiment during manufacturing (seventh part).

FIG. 10 is a cross-sectional view of the silicon carbide semiconductor device of the embodiment during manufacturing (eighth part).

FIG. 11 is a table showing relationships between TiN film thickness, Vth fluctuation, and cracking.

FIG. 12 is a cross-sectional view showing the structure of a conventional silicon carbide semiconductor device.

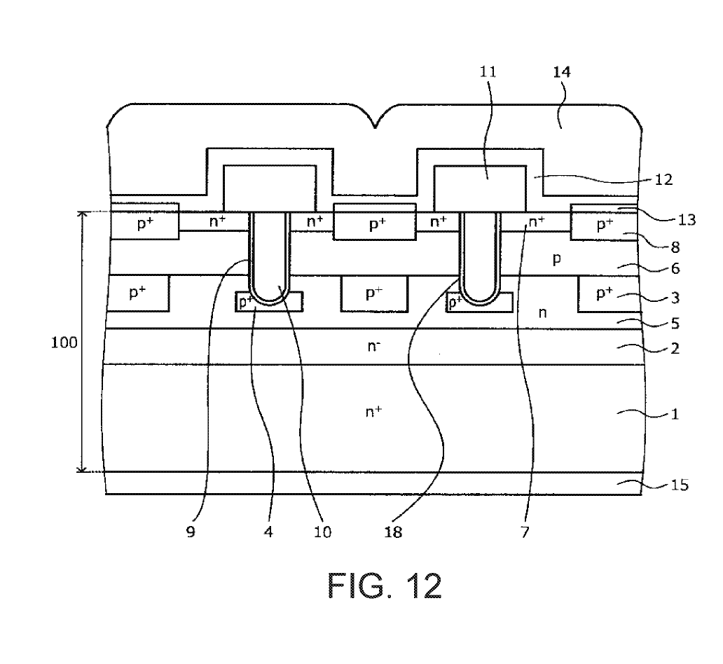

### DETAILED DESCRIPTION OF EMBODIMENTS

Preferable embodiments of a silicon carbide semiconductor device and a method of manufacturing a silicon carbide semiconductor device according to the present disclosure will be explained in detail below with reference to the attached drawings. In the present specification and attached drawings, layers or areas marked with an “n” or “p” signify that electrons or holes are majority carriers, respectively. The “+” or “−” attached to the “n” or “p” respectively signify higher impurity concentrations and lower impurity concentrations, respectively, than layers or areas without these marks. In the explanation of the embodiments below and the attached drawings, the same reference characters are attached to similar configurations and repetitive descriptions will be omitted.

### EMBODIMENTS

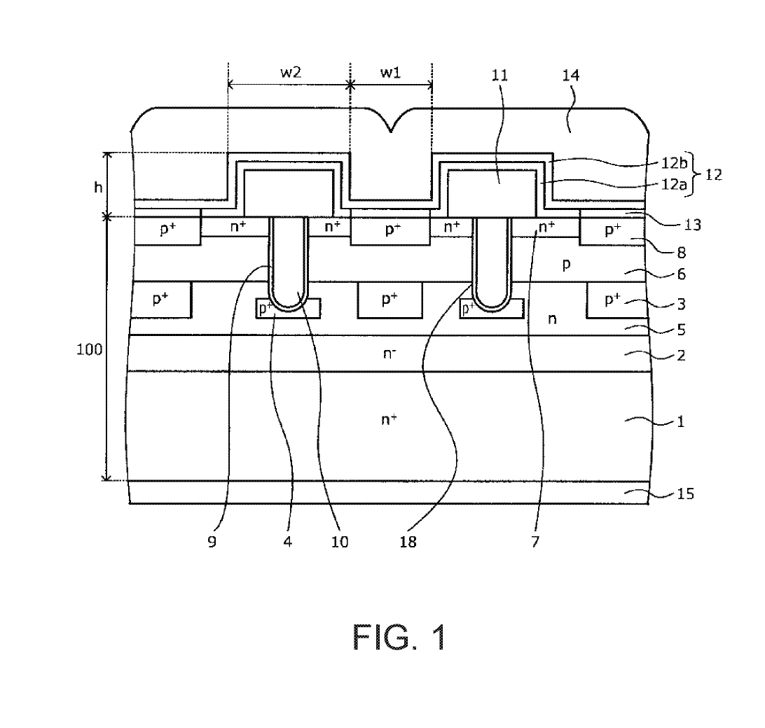

A semiconductor device of the present embodiment is formed using a semiconductor with a wider bandgap than silicon (hereinafter, wide bandgap semiconductor). The structure of a semiconductor device (silicon carbide semiconductor device) that uses silicon carbide (SiC), for example, as the wide bandgap semiconductor will be described as an example. FIG. 1 is a cross-sectional view of a structure of a silicon carbide semiconductor device according to the embodiment. FIG. 1 shows only two unit cells (functional units of the device), and the other unit cells adjacent to these unit cells are not shown in the drawings. The silicon carbide semiconductor device according to the embodiment shown in FIG. 1 is a MOSFET including a MOS gate on the front surface (p-type base layer 6 side surface) side of a semiconductor substrate made of silicon carbide (silicon carbide substrate: semiconductor chip).

The silicon carbide substrate 100 is formed by epitaxially growing an n⁻ drift region 2 and a p-type base layer (second conductivity layer of second conductivity type) 6 in the stated order on an n⁺ support substrate made of silicon carbide (n⁺ silicon carbide substrate: silicon carbide substrate of first conductivity type). The MOS gate is constituted by a p-type base layer 6, n⁺ source regions (first semiconductor regions of first conductivity type) 7, p⁺ contact regions 8, a trench 18, a gate insulating film 9, and a gate electrode 10. Specifically, an n-type region (hereinafter, n-type current spreading region) 5 is provided on the surface layer of the n drift region 2 on the source side (source electrode 14 side) so as to contact the p-type base layer 6. The n-type current spreading region 5 is a so-called CSL (current spreading layer) for reducing spread resistance of carriers. The n-type current spreading region 5 is provided uniformly in a direction parallel (hereinafter, the horizontal direction) to the substrate front surface (front surface of the silicon carbide substrate 100), for example.

First p⁺ regions 3 and second p⁺ regions 4 are each selectively provided inside the n-type current spreading region 5. The second p⁺ region 4 is provided so as to cover the bottom surface and bottom surface corner portions of the trench 18. The bottom surface corner portions of the trench 18 are the boundaries between the bottom surface and the side walls of the trench 18. The second p⁺ region 4 is provided from a position deeper toward the drain side than the interface between the p-type base layer 6 and n-type current spreading region 5 to a depth that does not reach the interface between the n-type current spreading region 5 and n drift region 2. Providing the second p⁺ region 4 makes it possible to form a pn junction between the second p⁺ region 4 and n-type current spreading region 5 near the bottom surface of the trench 18.

The first p⁺ regions 3 are provided between the adjacent trenches 18 (mesa parts) so as to be separated from the second p⁺ regions 4 and in contact with the p-type base layer 6. The first p⁺ region 3 may have a portion extending toward the trench 18 side and partially contacting the second p⁺ region 4. The first p⁺ region 3 is provided from the interface between the p-type base layer 6 and n-type current spreading region 5 to a depth that does not reach the interface between the n-type current spreading region 5 and n drift region 2. By providing the first p⁺ region 3, it is possible to form a pn junction between the first p⁺ region 3 and n-type current spreading region 5 between the adjacent trenches 18 and at a position that is deeper toward the drain side than the bottom surface of the trench 18. By forming pn junctions among the first p⁺ region 3, second p⁺ region 4, and n-type current spreading region 5 in this manner, it is possible to prevent a high electric field from being applied to the portion of the gate insulating film 9 on the bottom surface of the trench 18.

N⁺ source regions 7 and p⁺ contact regions 8 are selectively provided inside the p-type base layer 6 so as to contact one another. The depth of the p⁺ contact region 8 may be deeper than the n⁺ source region 7, for example.

The trench 18 penetrates from the substrate front surface through the n⁺ source region 7 and p-type base layer 6 to reach the n-type current spreading region 5. The gate insulating film 9 is provided inside the trench 18 along the side walls of the trench 18, and the gate electrode 10 is provided on the inner side of the gate insulating film 9. The source side end of the gate electrode 10 can either protrude or not protrude outward from the substrate front surface. The gate electrode 10 is electrically connected to a gate pad (not shown) by an unillustrated part.

An interlayer insulating film 11 provided to cover the gate electrode 10 is disposed on the entire front surface side of the silicon carbide substrate 100. The interlayer insulating film 11 is PSG and BPSG laminated in the stated order, for example. The concentration of B in BPSG (borophosphosilicate glass) is 6 to 7.5 mol %, for example, and the concentration of P is BPSG is 1 to 3 mol %, for example. The film thickness of PSG is 40 to 200 nm, and the film thickness of BPSG is 200 to 1,000 nm. PSG is provided on the bottom side (drain electrode 15 side) of BPSG in order to prevent the B or P in the BPSG from intruding into the silicon carbide substrate 100.

The contact electrode 13 contacts the n⁺ source region 7 and p⁺ region 8 via a contact hole formed in the interlayer insulating film 11 and is electrically connected to the n⁺ source region 7 and p⁺ contact region 8. The contact electrodes 13 are formed by silicidation of Ni. A trench contact may be provided instead of the contact hole, and the contact electrode may contact the n⁺ source region 7 at the side walls of the trench contact and contact the p⁺ contact region 8 at the bottom surface of the trench contact.

A TiN film 12a is provided on substantially all regions on the front surface side of the silicon carbide substrate 100 that exclude the region where the contact electrode 13 contacts p-type base layer 6 through the p⁺ contact region 8. The TiN film 12a has a thickness of 10 to 80 nm. The TiN film 12a is more preferably 20 to 70 nm.

A Ti/TiN/Ti film 12b deposited in the order of Ti, TiN, Ti is provided on the TiN film 12a and contact electrode 13. The barrier metal 12 is formed by the TiN film 12a and Ti/TiN/Ti film 12b. The barrier metal 12 is provided between the source electrode 14 and interlayer insulating film 11 in order to prevent diffusion of metal atoms from the source electrode 14 to the gate electrode 10, for example.

Setting the thickness of the TiN film 12a to 10 nm or more prevents the effects of high temperature or light irradiation during the step of silicidation of Ni of the contact electrode 13, and further prevents the effects of plasma in the Ti etching step during forming the Ti/TiN/Ti film 12b. Thus, it is possible to prevent high temperature, light irradiation, and plasma from affecting the gate insulating film 9. Furthermore, it is possible to prevent Ni from intruding into n-type regions in the step of silicidation of Ni of the contact electrode 13. Setting the thickness of the TiN film 12a to 10 nm or more in this manner makes it possible to prevent fluctuations in threshold voltage Vth and deterioration in semiconductor device characteristics.

Moreover, setting the thickness of the TiN film 12a to 100 nm or less makes it possible for deformation of the TiN film 12a at the temperature during the step of silicidation of Ni to not cause cracking in the BPSG of the interlayer insulating film 11. Thus, it is possible to prevent a reduction in insulating characteristics of the interlayer insulating film 11 due to cracking of the BPSG. Setting the thickness of the TiN film 12a to 100 nm or less in this manner makes it possible to prevent fluctuations in threshold voltage Vth and deterioration in semiconductor device characteristics.

The source electrode (first electrode) 14 contacts the n⁺ source region 7 and p⁺ contact region 8 via the contact electrode 13 and is electrically insulated from the gate electrode 10 by the interlayer insulating film 11. The source electrode 14 can be a two-layer structure of a Ti film and an Al—Si film, for example. The Al—Si film is an aluminum film containing 1% silicon, for example. A drain electrode (second electrode) 15 is provided on the rear surface of the silicon carbide substrate 100 (rear surface of the n⁺ silicon carbide substrate 1, which serves as the n⁺ drain region).

Furthermore, in the embodiment, the interval w1 between the interlayer insulating films 11, which includes the barrier metal 12, is approximately 1 to 3 am, for example, and the width w2 of the interlayer insulating film 11, which includes the barrier metal 12, is approximately 2 am, for example, and the height h of the interlayer insulating film 11, which includes the barrier metal 12, is approximately 0.5 to 1.5 am, for example.

(Method of Manufacturing Silicon Carbide Semiconductor Device of Embodiment)

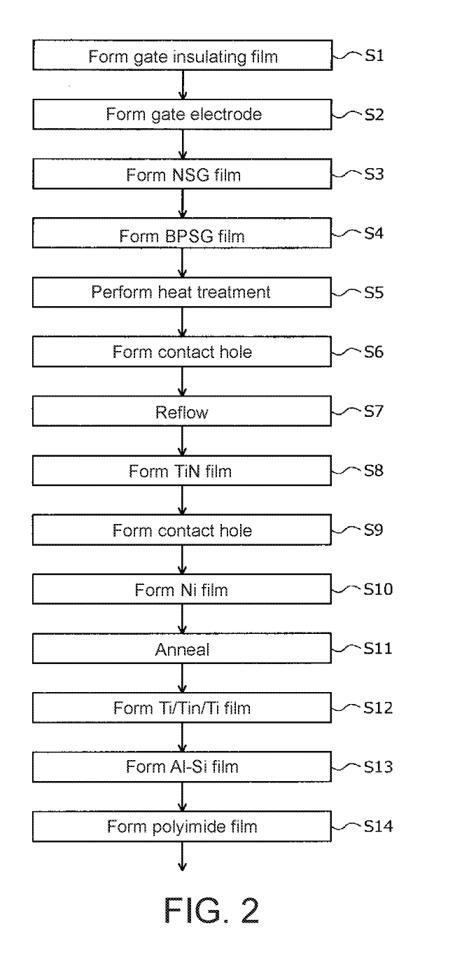

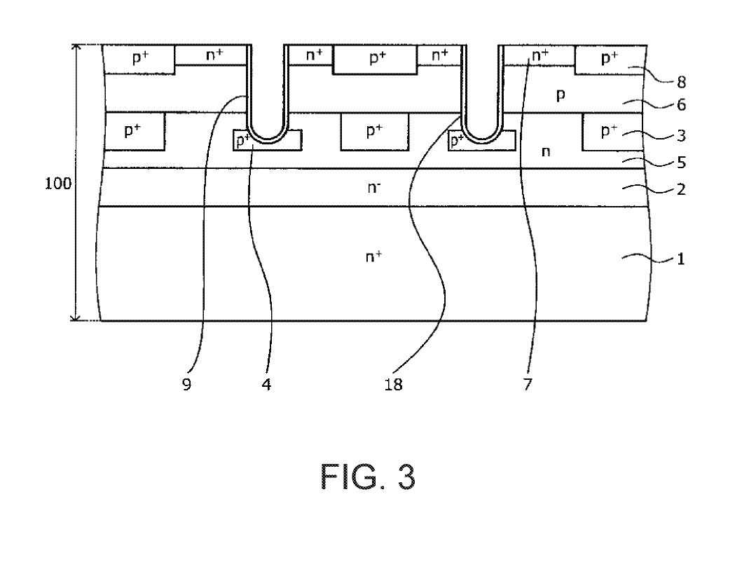

Next, a method of manufacturing a semiconductor device according to the embodiment will be described. FIG. 2 is a flowchart showing an overview of a part of the process for a method of manufacturing a silicon carbide semiconductor device of the embodiment. FIGS. 3 to 10 are cross-sectional views of the silicon carbide semiconductor device of the embodiment during the manufacturing thereof. First, the n⁺ silicon carbide substrate 1, which serves as the n⁺ drain region, is prepared. Next, the n drift layer 2 described above is epitaxially grown on the front surface of the n⁺ silicon carbide substrate 1. Next, via epitaxial growth, photolithography, and p-type impurity ion implantation, the n-type current spreading region 5 is formed on the front surface layer of the n⁻ drift layer 2, and the first p⁺ regions 3 and second p⁺ regions 4 are selectively formed inside the n-type current spreading region 5.

Next, the p-type base layer 6 is epitaxially grown on the n-type current spreading region 5. These foregoing steps form a silicon carbide substrate (semiconductor wafer) 100 in which the n drift layer 2, n-type current spreading region 5, and p-type base layer 6 are deposited in the stated order on the n⁺ silicon carbide substrate 1.

Next, photolithography and ion implantation of an n-type impurity are used to selectively form the n⁺ source regions 7 in the surface layer of the p-type base layer 6. Subsequently, photolithography and ion implantation of a p-type impurity are used to selectively form the p⁺ contact regions 8 in the surface layer of the p-type base layer 6 so as to contact the n⁺ source regions 7. The order in which the n⁺ source regions 7 and p⁺ contact regions 8 are formed may be switched. After all ion implantation has been completed, activation annealing is performed. The activation annealing is preferably performed at a temperature of 1500 to 1900° C., for example. During activation annealing, it is preferable that a C (carbon) film, for example, be formed by sputtering on the surface and then annealing be performed.

Next, photolithography and etching are used to form trenches 18 that penetrate through the n⁺ source regions 7 and p-type base layer 6 to reach the second p⁺ regions 4 inside the n-type current spreading region 5. An oxide film is used as the mask during forming of the trenches. After trench etching, it is possible to perform isotropic etching for removing damage to the trenches 18, or hydrogen annealing for rounding the bottoms of the trenches 18 or the corners of the openings of the trenches 18. It is also possible to perform only one of isotropic etching and hydrogen annealing. Furthermore, it is possible to perform hydrogen annealing after the isotropic etching has been performed.

The explanation will continue with reference to the flowchart in FIG. 2. Next, the gate insulating film 9 is formed on the front surface of the silicon carbide substrate 100 and along the inner walls of the trenches 18 (step S1). The gate insulating film 9 may be formed by a method whereby deposition is performed via a chemical reaction such as high temperature oxidation (HTO). Furthermore, after forming of the gate insulating film 9, POA (post oxidation annealing) may be performed. The state up to this step is shown in FIG. 3.

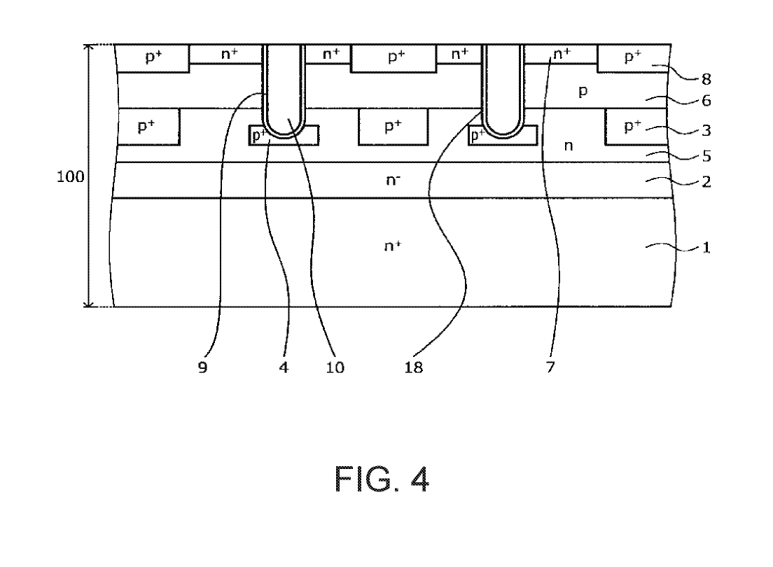

Next, polysilicon (poly-Si), for example, is deposited to fill the trenches 18, and is etched to form the gate electrode 10 by leaving polysilicon which will serve as the gate electrode 10 inside the trenches 18 (step S2). At such time, etch back may be performed to leave polysilicon further inside the trench relative to the substrate front part, or patterning and etching may be performed to make the polysilicon protrude outside from the substrate front part. In order to planarize the interlayer insulating film 11, it is preferable that the polysilicon be etched so as to remain inside the trench relative to the substrate front part. The state up to this step is shown in FIG. 4.

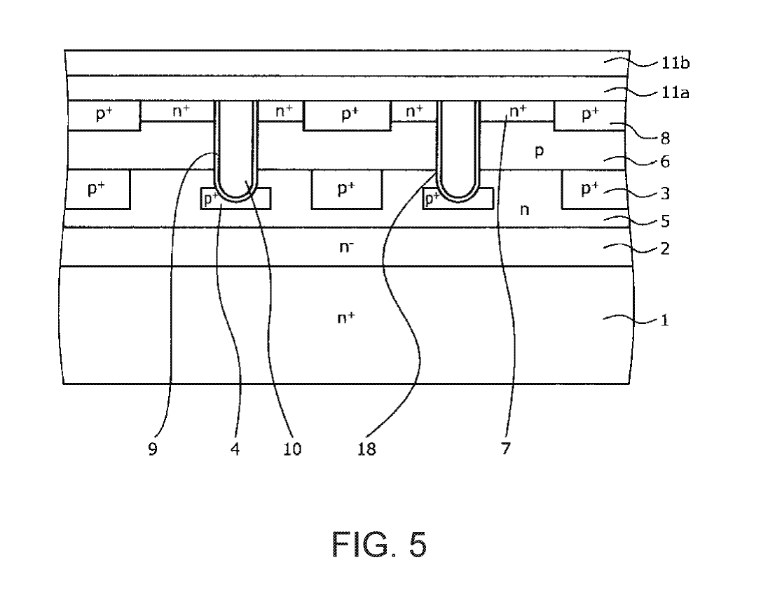

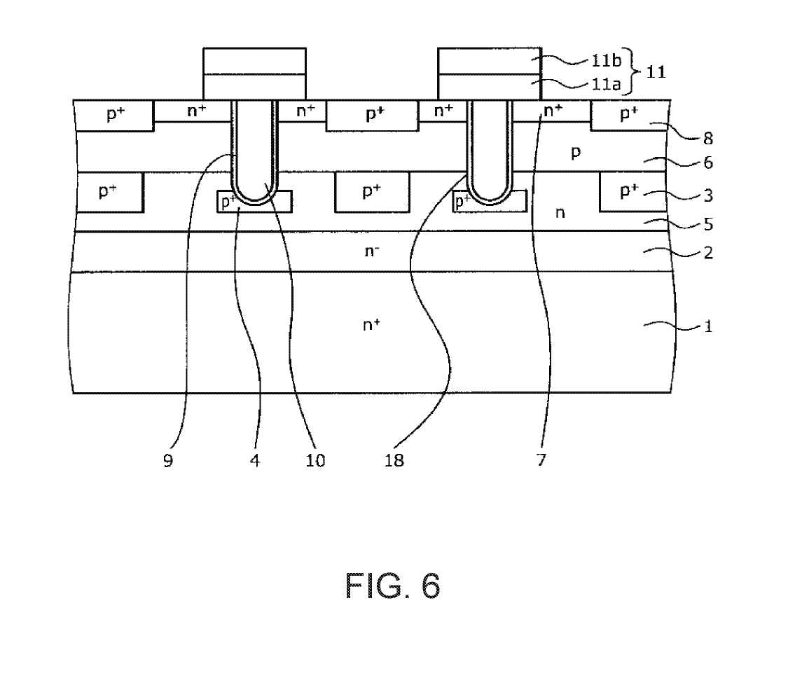

Next, an NSG (non-doped silicate glass) film 11a is formed at a thickness of 200 nm, for example, on the entire front surface of the silicon carbide substrate 100 (step S3). Next, a BPSG film 11b is formed at a thickness of 600 nm, for example, on the entire surface of the NSG film 11a (step S4). The BPSG film 11b is formed at an impurity concentration where reflow occurs at the temperature used during silicidation of Ni. The BPSG film 11b is formed at the concentration of B of 6 to 7.5 mol % and at the concentration of P of 1 to 3 mol %, for example. The state up to this step is shown in FIG. 5. Next, a thermal treatment is performed for 20 minutes at 970° C., for example (step S5). Next, the NSG film 11a, BPSG film 11b, and gate insulating film 9 are patterned to form contact holes (step S6). This exposes the n⁺ source region 7 and p⁺ contact region 8. The interlayer insulating film 11 is formed by the NSG film 11a and BPSG film 11b. The state up to this step is shown in FIG. 6.

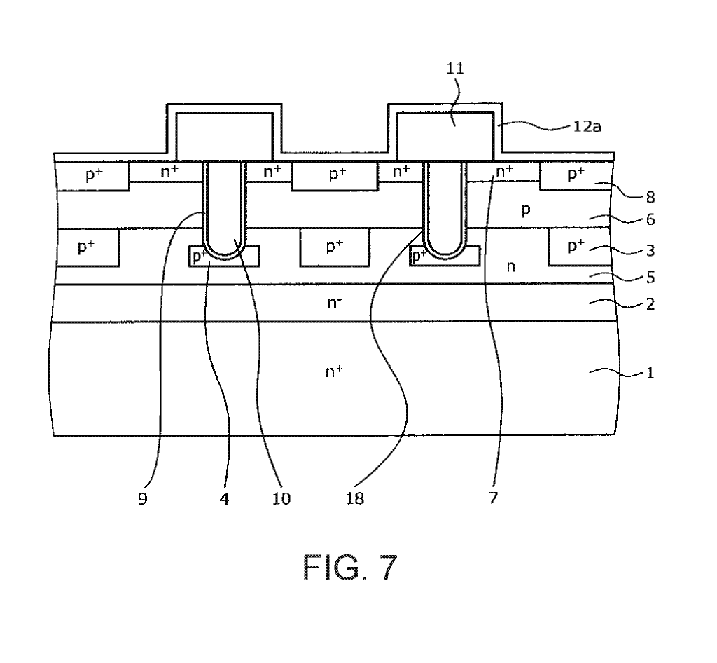

Next, in order to planarize the BPSG film 11b, a reflow treatment is performed for 30 minutes at a temperature of 950° C., for example (step S7). Next, the TiN film 12a is formed on the entire front surface of the silicon carbide substrate 100 and interlayer insulating film 11 (step S8). The TiN film 12a is formed in this manner before the step of silicidation in order to block the effects of infrared rays and plasma during the step of silicidation of Ni. The state up to this step is shown in FIG. 7.

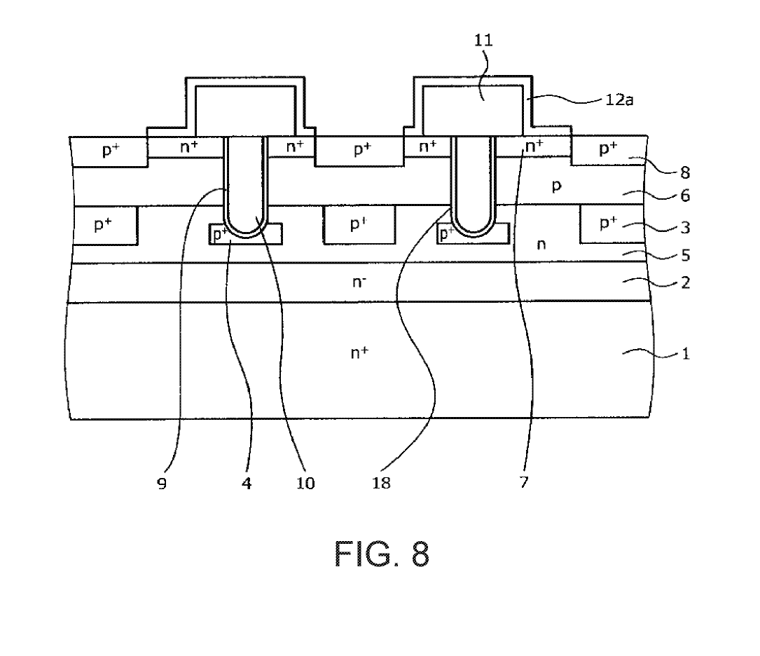

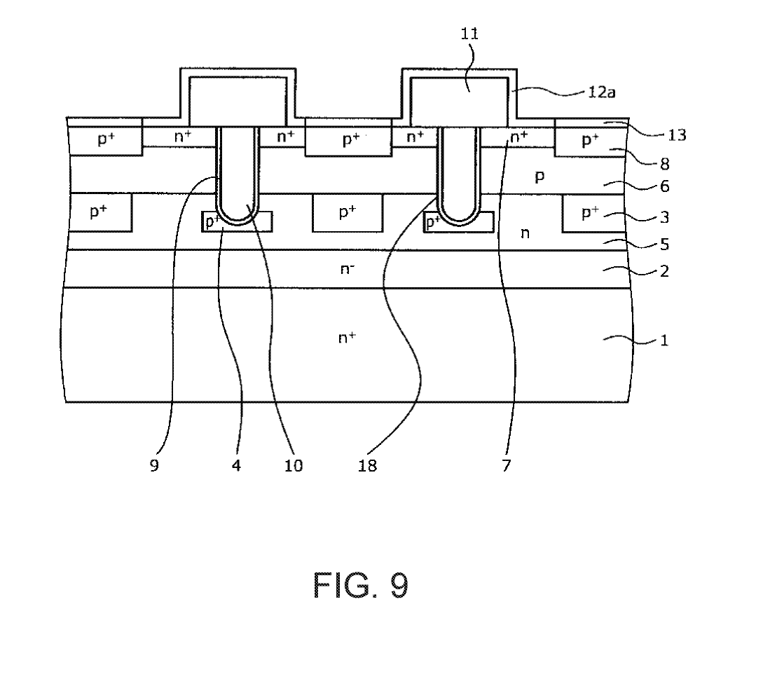

Next, the TiN film 12a is patterned to form contact holes (step S9). This exposes the p⁺ contact regions 8. The state up to this step is shown in FIG. 8. Next, a Ni film, which will serve as the contact electrode 13, is formed on the entire front surface of the silicon carbide substrate 100 and the interlayer insulating film 11 (step S10). Next, the Ni film is patterned and remains on the p⁺ contact regions 8. Next, an annealing treatment is performed for silicidation of the Ni film (step S11). This forms the contact electrode 13. The annealing treatment is performed at a temperature, such as 975° C., that is higher than the glass transition temperature of the BPSG in order to round the top of the BPSG. The state up to this step is shown in FIG. 9.

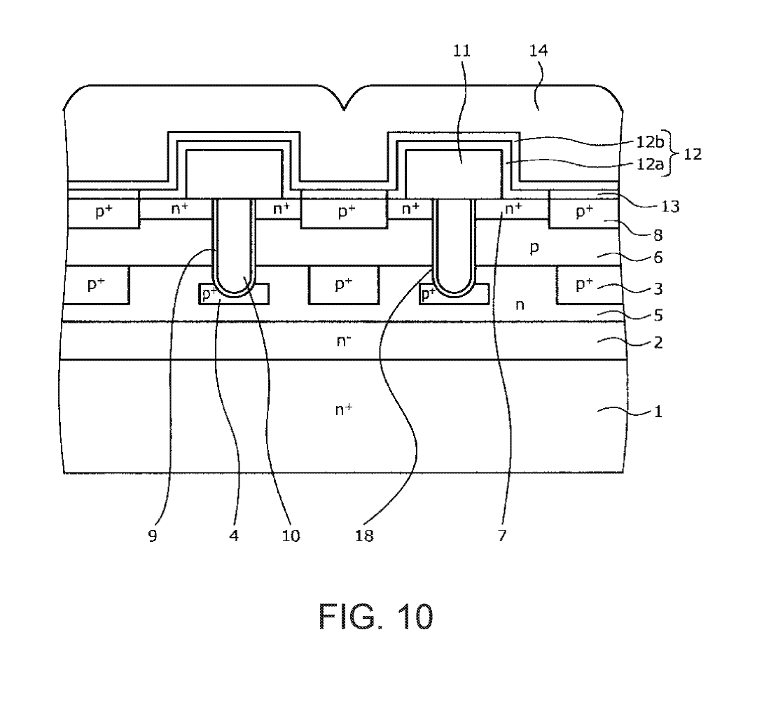

Next, the Ti/TiN/Ti film 12b is formed in the stated order on the contact electrode 13 and TiN film 12a (step S12). This forms the barrier metal 12. Next, an Al—Si film is formed as the source electrode 14 (step S13). The state up to this step is shown in FIG. 10. Next, a polyimide film (not shown) is formed on the source electrode 14 as a passivation film (step S14). This ends the process shown by the flowchart in FIG. 2 and forms the front surface of the silicon carbide substrate 100.

Next, a metal film such as a Ni film or Ti film is formed on the rear surface of the n⁺ silicon carbide substrate 1 by using sputter deposition or the like on the contact part of the drain electrode 15. The metal film may be a laminate film combining a plurality of Ni films and Ti films. Thereafter, annealing such as rapid thermal annealing (RTA) is performed for silicidation of the metal film to form an Ohmic contact. Afterward, a thick film such as a laminated film in which a Ti film, Ni film, and gold (Au), for example, are laminated in the stated order is formed by electron beam (EB) deposition or the like to form the drain electrode 15.

In the epitaxial growth and ion implantation described above, the n-type impurity (n-type dopant) may be nitrogen (N), phosphorous (P), arsenic (As), antimony (Sb), or the like, for example, which are n-type relative to silicon carbide. The p-type impurity (p-type dopant) may be boron (B), aluminum (Al), gallium (Ga), indium (In), thallium (Tl), or the like, for example, which are p-type relative to silicon carbide. In the above manner, the silicon carbide semiconductor device shown in FIG. 1 is completed.

As described above, in the embodiment, a TiN film is provided at a film thickness of 10 to 80 nm as the barrier metal. The thickness of the TiN film being 10 nm or greater makes it possible to prevent high temperature, light irradiation, and plasma from affecting the gate insulating film, thus making it possible to prevent intrusion of Ni into n-type regions in the step of silicidation. The thickness of the TiN being 100 nm or less makes it possible to prevent the BPSG from cracking. Therefore, it is possible to prevent fluctuations in the threshold voltage Vth and a deterioration of semiconductor device characteristics. The interlayer insulating film is laminated in the order of PSG and BPSG. This improves coverage characteristics with a source electrode made of Al—Si.

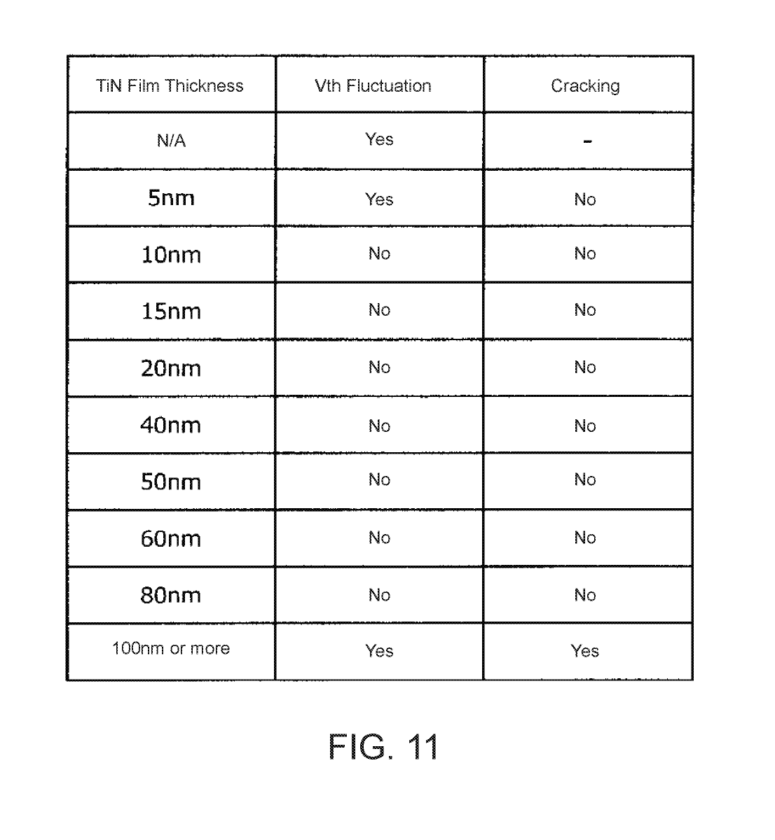

FIG. 11 is a table showing relationships between TiN film thickness, Vth fluctuation, and cracking. FIG. 11 shows the results of driving the silicon carbide semiconductor device of the embodiment and measuring the presence/absence of threshold voltage Vth fluctuations and cracking of the BPSG. As shown in FIG. 11, when no TiN film is provided or when the TiN film has a thickness of 100 nm or more, threshold voltage Vth fluctuations occur. Furthermore, when the TiN film has a thickness of 100 nm or more, cracking occurs in the BPSG. As shown by the table, when using BPSG in the interlayer insulating film, setting the thickness of the TiN film to 10 to 80 nm can prevent threshold voltage Vth fluctuations and cracking.

Various modifications can be made to the present embodiments described above without departing from the spirit of the present invention. For example, in the respective embodiments above, the dimensions, impurity concentrations, etc. of the respective parts can be modified in accordance with the desired specifications or the like. Furthermore, in the respective embodiments described above, a MOSFET was used as an example, but the present invention is not limited to this; the present invention is widely applicable to various types of silicon carbide semiconductor devices that conduct and block current via gate drive control based on a prescribed gate threshold voltage. Examples of silicon carbide semiconductor devices that are gate-driven include IGBTs (insulated gate bipolar transistors) and the like. Moreover, in the respective embodiments described above, an example is described in which silicon carbide was used as the wide bandgap semiconductor, but the present invention is also applicable to wide bandgap semiconductors other than silicon carbide, such as gallium nitride (GaN), for example. In addition, in the embodiments described above, the first conductivity type is n-type, and the second conductivity type is p-type, but the present invention is applicable even when the first conductivity type is p-type and the second conductivity type is n-type.

As described above, the silicon carbide semiconductor device and the method of manufacturing the silicon carbide semiconductor device of the present invention are useful for power semiconductor devices used in power supply devices or the like, such as in power converters or various types of industrial machinery, and are particularly suited for silicon carbide semiconductor devices having a trench gate structure.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A silicon carbide semiconductor device, comprising:
a silicon carbide substrate of a first conductivity type;
a first semiconductor layer of the first conductivity type, provided on or over a front surface of the silicon carbide substrate;
a second semiconductor layer of a second conductivity type, provided on the first semiconductor layer on a side opposite to the silicon carbide substrate;
first semiconductor regions of the first conductivity type, selectively provided in a top surface of the second semiconductor layer;
a trench penetrating through the second semiconductor layer and the first semiconductor regions and reaching the first semiconductor layer;
a gate electrode provided inside the trench with a gate insulating film interposed therebetween;
an interlayer insulating film covering the gate electrode;
a layer made of TiN covering the interlayer insulating film;
a contact electrode contacting the second semiconductor layer;
a first electrode over the layer made of TiN, electrically connecting to the contact electrode and the first semiconductor regions; and
a second electrode provided on a rear surface of the silicon carbide substrate,
wherein a film thickness of the layer made of TiN is 10 to 80 nm, and
wherein the interlayer insulating film is a laminate film of a layer of non-doped silicate glass and a layer of borophosphosilicate glass.

2. The silicon carbide semiconductor device according to claim 1, wherein the film thickness of the layer made of TiN is 20 to 70 nm.

3. The silicon carbide semiconductor device according to claim 1,
wherein a concentration of boron in the borophosphosilicate glass is 6 to 7.5 mol %,
wherein a concentration of phosphorous in the borophosphosilicate glass is 1 to 3 mol %,
wherein a film thickness of the non-doped silicate glass is 40 to 200 nm, and
wherein a film thickness of the borophosphosilicate glass is 200 to 1,000 nm.

4. The silicon carbide semiconductor device according to claim 1, wherein the layer made of TiN is formed in substantially all regions that excludes a region where the contact electrode contacts the second semiconductor layer.

5. The silicon carbide semiconductor device according to claim 2,
wherein a concentration of boron in the borophosphosilicate glass is 6 to 7.5 mol %,
wherein a concentration of phosphorous in the borophosphosilicate glass is 1 to 3 mol %,
wherein a film thickness of the non-doped silicate glass is 40 to 200 nm, and
wherein a film thickness of the borophosphosilicate glass is 200 to 1,000 nm.

6. The silicon carbide semiconductor device according to claim 2, wherein the layer made of TiN is formed in substantially all regions that exclude a region where the contact electrode contacts the second semiconductor layer.

7. The silicon carbide semiconductor device according to claim 1, wherein the contact electrode contacts the second semiconductor layer through a contact region of the second conductivity type selectively that is formed in the top surface of the second semiconductor layer, an impurity concentration of the contact region being higher than an impurity concentration of the second semiconductor layer.

8. The silicon carbide semiconductor device according to claim 1, wherein in the interlayer insulating film the layer of non-doped silicate glass is under the layer of borophosphosilicate glass.

9. A method of manufacturing a silicon carbide semiconductor device, the method comprising:
a first step of forming a first semiconductor layer of a first conductivity type on or over a front surface of a silicon carbide substrate of the first conductivity type;
a second step of forming a second semiconductor layer of a second conductivity type on the first semiconductor layer on a side opposite to the silicon carbide substrate;
a third step of selectively forming first semiconductor regions of the first conductivity type in a top surface of the second semiconductor layer;
a fourth step of forming a trench penetrating through the second semiconductor layer and the first semiconductor regions and reaching the first semiconductor layer;
a fifth step of forming a gate electrode inside the trench with a gate insulating film interposed therebetween;
a sixth step of forming an interlayer insulating film covering the gate electrode;
a seventh step of forming a layer made of TiN covering the interlayer insulating film;
an eighth step of forming a contact electrode contacting and the second semiconductor layer;
a ninth step of forming a first electrode over the layer made of TiN, electrically connecting to the contact electrode and the first semiconductor regions; and
a tenth step of forming a second electrode on a rear surface of the silicon carbide substrate,
wherein in the seventh step, the layer made of TiN is formed to have a film thickness of 10 to 80 nm, and
wherein in the sixth step, the interlayer insulating film is formed of a laminate film of a layer of non-doped silicate glass and a layer of borophosphosilicate glass.

10. The method of manufacturing the silicon carbide semiconductor device according to claim 9,
wherein, after the seventh step is performed, the eighth step is performed, and
wherein in the eighth step, a thermal treatment is performed during forming of the contact electrode.

11. The method of manufacturing the silicon carbide semiconductor device according to claim 9, wherein a temperature of the thermal treatment is higher than a glass transition temperature of the borophosphosilicate glass.

12. The method of manufacturing the silicon carbide semiconductor device according to claim 9, wherein the contact electrode contacts the second semiconductor layer through a contact region of the second conductivity type selectively that is formed in the top surface of the second semiconductor layer, an impurity concentration of the contact region being higher than an impurity concentration of the second semiconductor layer.

13. The method of manufacturing the silicon carbide semiconductor device according to claim 9, wherein in the interlayer insulating film, the layer of non-doped silicate glass is under the layer of borophosphosilicate glass.
